(19) United States
(12) Patent Application Publication
(10) Pub. No.: US 2026/0058635 A1
(43) Pub. Date: Feb. 26, 2026

(54) ODD OVER-MODED BULK ACOUSTIC WAVE DEVICES

(71) Applicant: Skyworks Global Pte. Ltd., Singapore (SG)

(72) Inventors: Benjamin Paul Abbott, Irvine, CA (US); Alexandre Augusto Shirakawa, Cardiff by the Sea, CA (US); David Albert Feld, Los Altos, CA (US); Kwang Jae Shin, Yongin-si (KR)

(21) Appl. No.: 19/304,729

(22) Filed: Aug. 20, 2025

Related U.S. Application Data
(60) Provisional application No. 63/685,331, filed on Aug. 21, 2024.

(51) Int. Cl. H03H 9/17; H03H 3/02; H03H 9/02

(52) U.S. Cl. CPC H03H 9/178; H03H 3/02; H03H 9/02102; H03H 9/173; H03H 9/175

(57) ABSTRACT

Aspects and embodiments disclosed herein include a bulk acoustic wave (BAW) device comprising a first electrode, a second electrode, a stack of at least two first piezoelectric material layers of the same polarity type sandwiched between the first electrode and the second electrode, and a first interposer sandwiched between the at least two first piezoelectric material layers and including at least one intermediate electrode, the BAW device being configured to excite an even overtone mode as the main mode of operation.

### CROSS-REFERENCE TO RELATED APPLICATIONS

This application claims priority under 35 U.S.C. § 119(e) to U.S. Provisional Patent Application Ser. No. 63/685,331, titled “ODD OVER-MODED BULK ACOUSTIC WAVE DEVICES,” filed Aug. 21, 2024, the entire content of which is incorporated herein by reference for all purposes.

### BACKGROUND

### Field

Embodiments of this disclosure relate to acoustic wave devices, such as bulk acoustic wave devices.

### Description of the Related Technology

An acoustic wave filter can include a plurality of resonators arranged to filter a radio frequency signal. Example acoustic wave filters include surface acoustic wave (SAW) filters and bulk acoustic wave (BAW) filters. BAW filters may include BAW resonators. Example BAW resonators include film bulk acoustic wave resonators and BAW solidly mounted resonators (SMRs). In BAW resonators, acoustic waves propagate in a bulk of a piezoelectric material layer.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

Communication applications operating in 5G technology and beyond may utilize BAW resonators with relatively high resonance frequencies of more than 5 GHz. As the resonance frequency of a BAW resonator depends proportionally to the acoustic velocity within material layers of the BAW resonator and inversely proportionally to the thickness of the piezoelectric material film of the BAW resonator, high-frequency BAW resonators typically employ thin piezoelectric material films. Such thin piezoelectric films may lead to an undesirable lowering of power-handling capacities, electromechanical coupling factors, and quality (Q) factors. Moreover, mass-loading effects of the top and bottom electrode layers have a stronger influence in BAW resonators with very thin piezoelectric material films so that lighter electrodes with smaller electrode areas for impedance matching may equally lead to decreased electrical conductivity, which in turn may negatively affect Q factors and electromechanical coupling factors of the BAW resonators.

High-frequency BAW resonators with decreased piezoelectric material film thicknesses may suffer from a decrease in resonator area for a fixed impedance value so that the ratio between area and periphery decreases, regardless of actual resonator shape. Thus, the efficacy of acoustic energy confinement may be lowered, leading to a reduced acoustic Q. Furthermore, a trade-off between filter bandwidth and filter loss is often made due to the constraints in ratios of electrode thickness to piezoelectric material layer thickness to maintain the desired coupling.

Approaches utilizing simple overtone scaling with a uniform piezoelectric material layer combat the thickness problem, but at the same time may suffer from degraded coupling by the square of the overtone mode. Alternatively, using oppositely polarized piezoelectric material layers to simultaneously increase the total piezoelectric material layer thickness and avoid any decrease in electromechanical coupling may in some instances be difficult to implement because the deposition techniques utilized may impact the material quality. As a result, it is desirable to find other solutions for high-frequency BAW resonators that do not rely on very thin piezoelectric material layers.

### SUMMARY

The innovations described in the claims each have several aspects, no single one of which is solely responsible for its desirable attributes. Without limiting the scope of the claims, some prominent features of this disclosure will now be briefly described.

According to some implementations, the present disclosure relates to a bulk acoustic wave (BAW) device. The BAW device includes a first electrode, a second electrode, a stack of at least two first piezoelectric material layers of the same polarity type sandwiched between the first electrode and the second electrode, and a first interposer sandwiched between the at least two first piezoelectric material layers. The first interposer includes at least one intermediate electrode. The BAW device is configured to excite an even overtone mode as the main mode of operation.

In some embodiments, the BAW device further includes a raised frame structure outside of a middle area of an active region of the BAW device. In several embodiments, the raised frame structure includes a first raised frame layer positioned between one of the first and second electrodes and the stack of at least two first piezoelectric material layers. In some embodiments, the first raised frame layer has a lower acoustic impedance than the first or second electrode.

In accordance with a few embodiments, the first raised frame layer is a silicon dioxide layer. According to a number of embodiments, the acoustic impedance of the first raised frame layer is lower than an acoustic impedance of the at least two first piezoelectric material layers. In various embodiments, the first raised frame layer is disposed in a raised frame domain of the BAW device along an edge of the active domain. In accordance with several embodiments, the BAW device further includes a recessed frame domain between the raised frame domain and the middle area. According to some embodiments, the first raised frame layer is positioned between the stack of at least two first piezoelectric material layers and the first electrode.

According to a few embodiments, the first interposer includes a first intermediate electrode, a second intermediate electrode, and a second piezoelectric material layer sandwiched between the first intermediate electrode and the second intermediate electrode. According to some embodiments, the first intermediate electrode and the second intermediate electrode are ruthenium (Ru), molybdenum (Mo), tungsten (W), iridium (Ir), platinum (Pt), osmium (Os), rhenium (Re), aluminum (Al), beryllium (Be), or titanium (Ti) electrodes. In some embodiments, the second piezoelectric material layer is of a polarity type opposite to the polarity type of the at least two first piezoelectric material layers. According to a number of embodiments, the at least two first piezoelectric material layers and the second piezoelectric material layer include aluminum nitride (AlN) layers. The at least two first piezoelectric material layers may be AlN layers doped with scandium (Sc), yttrium (Y), hafnium (Hf), zirconium (Zr), titanium (Ti), magnesium (Mg), chromium (Cr), or boron (B). In several embodiments, the polarity type of the at least two first piezoelectric material layers is Al-polar and the polarity type of the second piezoelectric material layer is N-polar. In some alternative embodiments, the polarity type of the at least two first piezoelectric material layers is N-polar and the polarity type of the second piezoelectric material layer is Al-polar.

In various embodiments, the stack of at least two first piezoelectric material layers of the same polarity type includes at least three first piezoelectric material layers sandwiched between the first electrode and the second electrode. The first interposer may be sandwiched between a first one and a second one of the at least three first piezoelectric material layers. The BAW device may further include a second interposer sandwiched between the second one and a third one of the at least three first piezoelectric material layers. According to a number of embodiments, the at least three first piezoelectric material layers include aluminum nitride (AlN) layers. The at least three first piezoelectric material layers may be AlN layers doped with scandium (Sc), yttrium (Y), hafnium (Hf), zirconium (Zr), titanium (Ti), magnesium (Mg), chromium (Cr), or boron (B).

In a number of embodiments, the first interposer includes a first intermediate electrode, a second intermediate electrode, and a temperature compensation layer sandwiched between the first intermediate electrode and the second intermediate electrode. In various embodiments, the temperature compensation layer includes a silicon dioxide layer. According to a few embodiments, the temperature compensation layer includes a silicon dioxide layer doped with fluorine (F), boron (B), carbon (C), phosphorus (P), or nitrogen (N). According to some embodiments, the first intermediate electrode and the second intermediate electrode are ruthenium (Ru), molybdenum (Mo), tungsten (W), iridium (Ir), platinum (Pt), osmium (Os), rhenium (Re), aluminum (Al), beryllium (Be), or titanium (Ti) electrodes.

In various embodiments, the intermediate electrode of the first interposer is a ruthenium (Ru), molybdenum (Mo), tungsten (W), iridium (Ir), platinum (Pt), osmium (Os), rhenium (Re), aluminum (Al), beryllium (Be), or titanium (Ti) electrode. In a number of embodiments, the at least two first piezoelectric material layers are AlN layers doped with scandium (Sc), yttrium (Y), hafnium (Hf), zirconium (Zr), titanium (Ti), magnesium (Mg), chromium (Cr), or boron (B). According to several embodiments, the Sc content of the AlN layers is at least 15%. In a few embodiments, the Sc content of the AlN layers is about 20%.

According to various embodiments, a thickness of the first intermediate electrode and the second intermediate electrode of the first interposer is larger than a thickness of the first electrode and the second electrode. In several embodiments, the thickness of the first intermediate electrode and the second intermediate electrode of the first interposer is at least twice as large as the thickness of the first electrode and the second electrode.

According to some implementations, the present disclosure relates to a film bulk acoustic wave resonator device. The film bulk acoustic wave resonator device includes a substrate and first and second conductive layers implemented over the substrate. The film bulk acoustic wave resonator device further includes a stack of at least two first piezoelectric material layers of the same polarity type sandwiched between the first conductive layer and the second conductive layer. The film bulk acoustic wave resonator device further includes a first interposer sandwiched between the at least two first piezoelectric material layers. The first interposer includes at least one intermediate conductive layer. The film bulk acoustic wave resonator device is configured to excite an even overtone mode as the main mode of operation.

In some embodiments, the film bulk acoustic wave resonator device further includes a raised frame structure outside of a middle area of an active region of the film bulk acoustic wave resonator device. In several embodiments, the raised frame structure includes a first raised frame layer positioned between one of the first and second conductive layers and the stack of at least two first piezoelectric material layers. In some embodiments, the first raised frame layer has a lower acoustic impedance than the first or second conductive layer.

In accordance with a few embodiments, the first raised frame layer is a silicon dioxide layer. According to a number of embodiments, the acoustic impedance of the first raised frame layer is lower than an acoustic impedance of the at least two first piezoelectric material layers. In various embodiments, the first raised frame layer is disposed in a raised frame domain of the film bulk acoustic wave resonator device along an edge of the active domain. In line with several embodiments, the film bulk acoustic wave resonator device further includes a recessed frame domain between the raised frame domain and the middle area. According to some embodiments, the first raised frame layer is positioned between the at least two first piezoelectric material layers and the first conductive layer.

According to a few embodiments, the first interposer includes a first intermediate conductive layer, a second intermediate conductive layer, and a second piezoelectric material layer sandwiched between the first intermediate conductive layer and the second intermediate conductive layer. According to some embodiments, the first intermediate conductive layer and the second intermediate conductive layer are formed of ruthenium (Ru), molybdenum (Mo), tungsten (W), iridium (Ir), platinum (Pt), osmium (Os), rhenium (Re), aluminum (Al), beryllium (Be), or titanium (Ti). In some embodiments, the second piezoelectric material layer is of a polarity type opposite to the polarity type of the at least two first piezoelectric material layers. According to a number of embodiments, the at least two first piezoelectric material layers and the second piezoelectric material layer include aluminum nitride (AlN) layers. The at least two first piezoelectric material layers may be AlN layers doped with scandium (Sc), yttrium (Y), hafnium (Hf), zirconium (Zr), titanium (Ti), magnesium (Mg), chromium (Cr), or boron (B). In several embodiments, the polarity type of the at least two first piezoelectric material layers is Al-polar and the polarity type of the second piezoelectric material layer is N-polar. In some alternative embodiments, the polarity type of the at least two first piezoelectric material layers is N-polar and the polarity type of the second piezoelectric material layer is Al-polar.

In various embodiments, the stack of at least two first piezoelectric material layers of the same polarity type includes at least three first piezoelectric material layers sandwiched between the first conductive layer and the second conductive layer. The first interposer is sandwiched between a first one and a second one of the at least three first piezoelectric material layers. The BAW device further includes a second interposer sandwiched between the second one and a third one of the at least three first piezoelectric material layers. According to a number of embodiments, the at least three first piezoelectric material layers include aluminum nitride (AlN) layers.

In a number of embodiments, the first interposer includes a first intermediate conductive layer, a second intermediate conductive layer, and a temperature compensation layer sandwiched between the first intermediate conductive layer and the second intermediate conductive layer. In various embodiments, the temperature compensation layer includes a silicon dioxide layer. In a few embodiments, the temperature compensation layer includes a silicon dioxide layer doped with fluorine (F), boron (B), carbon (C), phosphorus (P), or nitrogen (N). According to some embodiments, the first intermediate conductive layer and the second intermediate conductive layer are formed of ruthenium (Ru), molybdenum (Mo), tungsten (W), iridium (Ir), platinum (Pt), osmium (Os), rhenium (Re), aluminum (Al), beryllium (Be), or titanium (Ti).

In various embodiments, the at least one intermediate conductive layer of the first interposer is formed of ruthenium (Ru), molybdenum (Mo), tungsten (W), iridium (Ir), platinum (Pt), osmium (Os), rhenium (Re), aluminum (Al), beryllium (Be), or titanium (Ti). In a number of embodiments, the at least two first piezoelectric material layers are AlN layers doped with scandium (Sc), yttrium (Y), hafnium (Hf), zirconium (Zr), titanium (Ti), magnesium (Mg), chromium (Cr), or boron (B). According to several embodiments, the Sc content of the AlN layers is at least 15%. In a few embodiments, the Sc content of the AlN layers is about 20%.

According to various embodiments, a thickness of the first intermediate conductive layer and the second intermediate conductive layer of the first interposer is larger than a thickness of the first conductive layer and the second conductive layer. In several embodiments, the thickness of the first intermediate conductive layer and the second intermediate conductive layer of the first interposer is at least twice as large as the thickness of the first conductive layer and the second conductive layer.

According to some implementations, the present disclosure relates to a packaged module. The packaged module includes a packaging substrate and an acoustic wave filter on the packaging substrate and configured to filter a radio frequency signal. The acoustic wave filter includes a bulk acoustic wave (BAW) device. The BAW device includes a first electrode, a second electrode, a stack of at least two first piezoelectric material layers of the same polarity type sandwiched between the first electrode and the second electrode, and a first interposer sandwiched between the at least two first piezoelectric material layers. The first interposer includes at least one intermediate electrode. The BAW device is configured to excite an even overtone mode as the main mode of operation. The packaged module further includes a radio frequency component electrically coupled to the acoustic wave filter and positioned on the packaging substrate, the acoustic wave filter and the radio frequency component being enclosed within a common package.

According to some implementations, the present disclosure relates to a radio frequency front end (RFFE). The RFFE includes an acoustic wave filter configured to filter a radio frequency signal. The acoustic wave filter includes a plurality of acoustic wave resonators including a bulk acoustic wave (BAW) resonator. The BAW resonator includes a first electrode, a second electrode, a stack of at least two first piezoelectric material layers of the same polarity type sandwiched between the first electrode and the second electrode, and a first interposer sandwiched between the at least two first piezoelectric material layers. The first interposer includes at least one intermediate electrode. The BAW resonator is configured to excite an even overtone mode as the main mode of operation. The RFFE further includes a radio frequency amplifier coupled to the acoustic wave filter.

According to some implementations, the present disclosure relates to a wireless communication device. The wireless communication device includes an acoustic wave filter configured to filter a radio frequency signal. The acoustic wave filter includes a bulk acoustic wave (BAW) device. The BAW device includes a first electrode, a second electrode, a stack of at least two first piezoelectric material layers of the same polarity type sandwiched between the first electrode and the second electrode, and a first interposer sandwiched between the at least two first piezoelectric material layers. The first interposer includes at least one intermediate electrode. The BAW device is configured to excite an even overtone mode as the main mode of operation. The wireless communication device further includes an antenna operatively coupled to the acoustic wave filter, a radio frequency amplifier operatively coupled to the acoustic wave filter and configured to amplify a radio frequency signal, and a transceiver in communication with the radio frequency amplifier.

For purposes of summarizing the disclosure, certain aspects, advantages and novel features have been described herein. It is to be understood that not necessarily all such advantages may be achieved in accordance with any particular embodiment. Thus, aspects and embodiments disclosed herein may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 is a schematic cross-sectional view of a bulk acoustic wave (BAW) device with a single-layer single-gradient raised frame structure according to an embodiment.

FIG. 2A is a plan view of a multi-layer gradient raised frame BAW device according to another embodiment.

FIG. 2B is a plan view of a multi-layer raised frame odd over-moded BAW device according to another embodiment.

FIG. 3 is a cross-sectional diagram of a portion of the electrode and piezoelectric material stack of the odd over-moded BAW device of FIG. 1.

FIG. 4 is a cross-sectional diagram of a portion of the electrode and piezoelectric material stack of an odd over-moded BAW device according to another embodiment.

FIG. 5 is a cross-sectional diagram of a portion of the electrode and piezoelectric material stack of an odd over-moded BAW device according to another embodiment.

FIG. 6 is a cross-sectional diagram of a portion of the electrode and piezoelectric material stack of an odd over-moded BAW device according to another embodiment.

FIG. 7 is a cross-sectional diagram of a portion of the electrode and piezoelectric material stack of an odd over-moded BAW device according to another embodiment.

FIG. 8 is a cross sectional diagram of a solidly mounted odd over-moded BAW resonator according to another embodiment.

FIG. 9 is a schematic diagram of a ladder filter that includes a BAW resonator according to an embodiment.

FIG. 10 is a schematic diagram of a lattice filter that includes a BAW resonator according to an embodiment

FIG. 11 is a schematic diagram of a hybrid ladder lattice filter that includes a BAW resonator according to another embodiment.

FIG. 12A is a schematic diagram of an acoustic wave filter.

FIG. 12B is a schematic diagram of a duplexer that includes an acoustic wave filter according to another embodiment.

FIG. 12C is a schematic diagram of a multiplexer that includes an acoustic wave filter according to another embodiment.

FIG. 12D is a schematic diagram of another multiplexer that includes an acoustic wave filter according to another embodiment.

FIG. 12E is a schematic diagram of yet another multiplexer that includes an acoustic wave filter according to another embodiment.

FIG. 13 is a schematic block diagram of an illustrative packaged module according to another embodiment.

FIG. 14 is a schematic block diagram of another illustrative packaged module according to another embodiment.

FIG. 15 is a schematic block diagram of another illustrative packaged module according to another embodiment.

FIG. 16 is a schematic block diagram of another illustrative packaged module according to another embodiment.

FIG. 17 is a schematic block diagram of another illustrative packaged module according to another embodiment.

FIG. 18 is a schematic block diagram of a mobile device that includes acoustic wave filters with BAW resonators according to another embodiment.

FIG. 19 is a schematic diagram of a communication network.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As demand increases for filtering radio frequency signals with higher frequencies, acoustic wave resonators with higher resonant frequencies are desired. Bulk acoustic wave (BAW) resonators are moving to increasingly higher resonant frequencies approaching 10 gigahertz (GHz). Bulk acoustic wave (BAW) resonators can use a fundamental mode as a main mode. In such BAW resonators, higher resonant frequencies can be achieved by reducing the thickness of the piezoelectric material layer and/or electrode layers. BAW resonators with a thinner layer stack have generally provided higher resonant frequencies. Thinner electrodes can also contribute to a higher resonant frequency for a BAW resonator.

Thinner BAW piezoelectric material layer and/or electrode layer stacks present technical challenges. With a thinner stack, BAW resonators are typically more fragile. Overall thickness of thinner BAW stacks can be problematic for mechanical stability of a BAW resonator. BAW resonators with thin stacks can be problematic for post-release processing, such as trimming, applying photoresists, and/or other processing that applies stress on a BAW resonator structure. BAW resonators with relatively thin stacks can have relatively high resistivity. BAW resonators with relatively thin stacks can encounter technical challenges related to power handling. Moreover, thinner electrode layers can have higher electrode resistance that can reduce performance.

The resonance frequency of a BAW resonator is proportional to the acoustic velocity within the resonator stack divided by twice the resonator thickness. Therefore, to increase the frequency of a BAW resonator to frequencies above 6 GHz, one may utilize very thin resonator thicknesses using conventional materials. Due to the aforementioned difficulties and technical challenges, ever increasing frequencies set practical boundaries for the manufacturing of BAW resonators and, hence, BAW filters using conventional manufacturing techniques.

Aspects of this disclosure relate to solutions for BAW devices and/or BAW resonators which operate at higher frequencies while maintaining thicker piezoelectric material layers and/or electrode layers. Specifically, such BAW devices and/or BAW resonators are designed to operate at overtone frequencies of the fundamental resonance frequency. More particularly, the BAW devices and/or BAW resonators are configured to excite an even overtone mode as the main mode of operation, i.e., to operate on odd tones of the fundamental resonance frequency. BAW devices can operate with a harmonic mode as a main mode. BAW devices with a harmonic mode as a main mode can include stacked piezoelectric material layers with polarization inversion. The harmonic mode is an overtone mode. Overtone modes progress with alternating 180° longitudinal wavelengths through the electrode and piezoelectric material layer stack of a BAW devices or BAW resonator, that is, the longitudinal phase progression from top to bottom of the stack can be expressed by (n+1)·π radians, with n being the overtone index.

By proper selection of the doping of the piezoelectric material layer with scandium (Sc) or certain other elements, it is possible to achieve thicker piezoelectric material and electrode layers than can be managed using a standard resonator stack. This aids in maintaining the quality of the piezoelectric material layer and keeps the resistance values of the electrode layers low.

Although embodiments disclosed herein may be discussed with reference to bulk acoustic wave (BAW) devices, such as film bulk acoustic resonators or solidly mounted resonators (SMR), any suitable principles and advantages discussed herein can be applied to other acoustic wave devices, such as non-temperature compensated surface acoustic wave (SAW) devices, temperature compensated SAW (TC-SAW) devices and multilayer piezoelectric substrate (MPS) SAW devices, boundary wave devices, and Lamb wave devices as well.

Example odd over-moded BAW devices will now be discussed. BAW devices may be designed with a piezoelectric material and electrode layer stack by including a number N of piezoelectric material layers with alternating polarity, resulting in a BAW stack operating on the (N−1)^{th} overtone, i.e., the N^{th} tone. Odd over-moded BAW devices include piezoelectric material and electrode layer stacks having at least two piezoelectric material layers of the same polarity being interposed with at least one intermediate piezoelectric material layer and/or at least one intermediate electrode in between two of the adjacent piezoelectric material layers of the same polarity.

Any suitable principles and advantages of these BAW devices can be implemented in BAW resonators. Such BAW resonators may be used for acoustic wave filters. Such acoustic wave filters can filter radio-frequency signals. The electrode and piezoelectric material layer stacks disclosed herein can be implemented in BAW devices. In BAW devices, electrode and piezoelectric material layer stacks as disclosed herein can contribute to a higher resonant frequency for a given electrode thickness. A BAW device with an electrode and piezoelectric material layer stack in accordance with any suitable principles and advantages disclosed herein can have a resonant frequency of at least 6 GHz. A BAW device with an electrode and piezoelectric material layer stack in accordance with any suitable principles and advantages disclosed herein can be configured to excite an even overtone mode as the main mode of operation, and thus to have a resonant frequency in a range from 6 GHz to 15 GHz. In some of these instances, a BAW device can have a resonant frequency in a range from 6 GHz to 10 GHz. A BAW device with an electrode and piezoelectric material layer stack as disclosed herein can have a same resonant frequency as another BAW device with thinner piezoelectric material layers. BAW resonators, such as film bulk acoustic wave resonators and BAW SMRs, can include an electrode and piezoelectric material layer stack in accordance with any suitable principles and advantages disclosed herein.

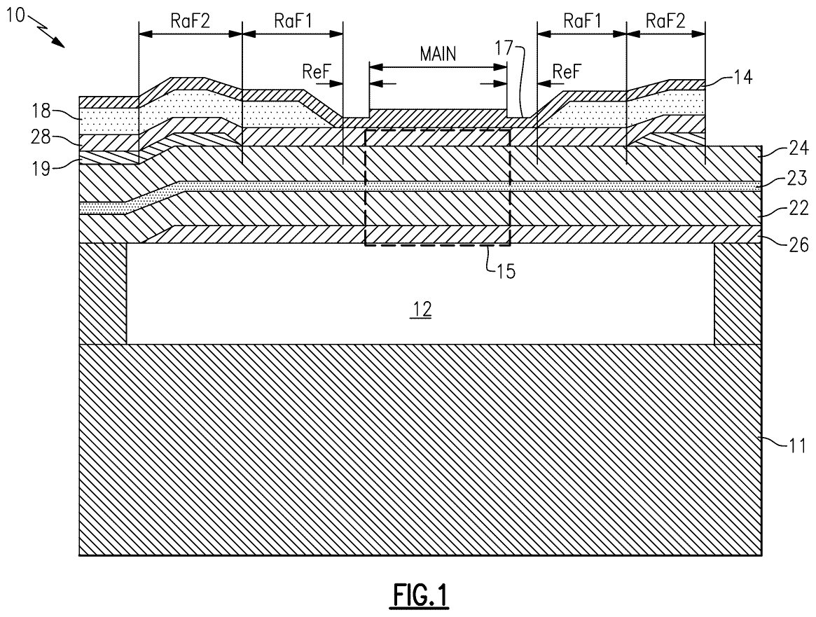

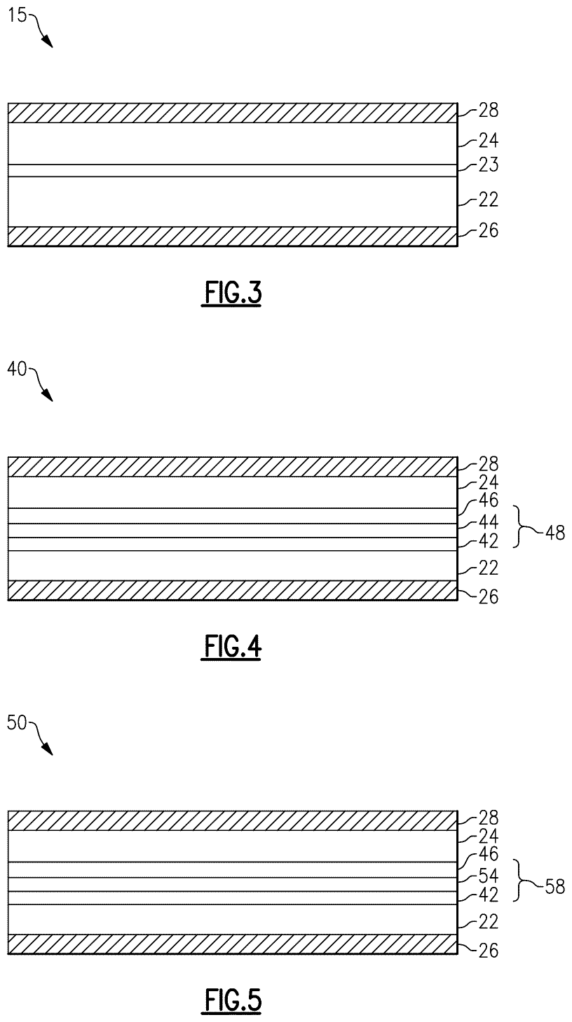

FIG. 1 is a cross sectional diagram of an odd over-moded BAW device 10 according to an embodiment. The odd over-moded BAW device 10 is configured to excite an even overtone mode as the main mode of operation. To that end, the odd over-moded BAW device 10 includes stacked piezoelectric material layers of the same polarity with either interposing piezoelectric material layers of opposing polarity or intermediate electrodes. As illustrated, the odd over-moded BAW device 10 includes a support substrate 11, an air cavity 12, a passivation layer 14, and an electrode and piezoelectric material layer stack 15. The electrode and piezoelectric material layer stack 15 includes at least two piezoelectric material layers 22 and 24, an interposing piezoelectric material layer or intermediate electrode 23, a first electrode 26, and a second electrode 28. Part of the electrode and piezoelectric material layer stack 15 of the odd over-moded BAW device 10 is shown in FIG. 3. The part of the electrode and piezoelectric material layer stack 15 is in a main acoustically active region of the odd over-moded BAW device 10. More details regarding the piezoelectric material layers 22 and 24, the interposing piezoelectric material layer or intermediate electrode 23, the first electrode 26, and the second electrode 28 will be discussed with reference to FIGS. 3 to 7.

An active region or active domain of the BAW device 10 can be where voltage is applied on opposing sides of the electrode and piezoelectric material layer stack 15 over an acoustic reflector, such as the air cavity 12 or a solid acoustic mirror. The illustrated BAW device 10 includes a main acoustically active region MAIN, a recessed frame region ReF with a recessed frame structure 17, a first raised frame region RaF1 with the first raised frame layer 18, and a second raised frame region RaF2 with a first raised frame layer 18 and a second raised frame layer 19. The main region MAIN can be a majority of the area of the BAW device 10. The main acoustically active region MAIN can provide a main mode of the BAW device 10. The main acoustically active region MAIN can be the central part of the active region that is free from the frame structures, such as raised and recessed frame structures. While the BAW device 10 includes the recessed frame structure 17 and the raised frame layers 18 and 19, other frame structures can alternatively or additionally be implemented. Moreover, an odd over-moded BAW device in accordance with any suitable principles and advantages disclosed herein can be implemented without a recessed frame structure and/or without a raised frame structure.

The first raised frame layer 18 is positioned between the second electrode 28 and the passivation layer 14. The first raised frame layer 18 can be a relatively high acoustic impedance material. For instance, the first raised frame layer 18 layer can include Mo, W, Ru, Ir, Cr, Pt, the like, or any suitable alloy thereof. The first raised frame layer 18 layer can be a metallic layer. In such embodiments, the first raised frame layer 18 can be referred to as a metal raised frame layer. Alternatively, the first raised frame layer 18 can be a suitable non-metal material with a relatively high density. In some instances, first raised frame layer 18 can be of the same material as the electrode 28 of the BAW device 10.

The second raised frame layer 19 can have a relatively lower acoustic impedance. The second raised frame layer 19 can have a lower acoustic impedance than the piezoelectric material layers of the BAW device 10. The second raised frame layer 19 can be an oxide, such as a silicon oxide. Such a second raised frame layer 19 can be referred to as an oxide raised frame layer. The second raised frame layer 19 can be a dielectric layer. The second raised frame layer 19 layer can include one or more of an oxide, a metal, or a polymer. The second raised frame layer 19 can include, for example, a SiO₂ layer, a SiN layer, a SiC layer, or any other suitable low acoustic impedance material. Because SiO₂ is already used in a variety of bulk acoustic wave devices, a SiO₂ second raised frame layer 19 can be relatively easy to manufacture.

The air cavity 12 is an example of an acoustic reflector. As illustrated, the air cavity 12 is etched into the support substrate 11. In some other applications, an air cavity can be over a support substrate. The air cavity 12 is positioned between the support substrate 11 and the first electrode 26. The support substrate 11 can be a silicon substrate. The support substrate 11 can be any other suitable support substrate.

The passivation layer 14 can be referred to as an upper passivation layer. The passivation layer 14 can be a silicon dioxide layer or any other suitable passivation layer, such as aluminum oxide, silicon carbide, aluminum nitride, silicon nitride, silicon oxynitride, or the like. The passivation layer 14 can have different thicknesses in different regions of the BAW device 10. Part of the passivation layer 14 can form at least part of a frame structure. As illustrated in FIG. 1, the passivation layer 14 is thinner in the recessed frame region ReF than in the MAIN region. The recessed frame structure 17 includes the thinner part of the passivation layer that is non-overlapping with raised frame layers 18 and 19. While not shown in FIG. 1, the BAW device 10 can include a second passivation layer positioned between the air cavity 12 and the first electrode 26.

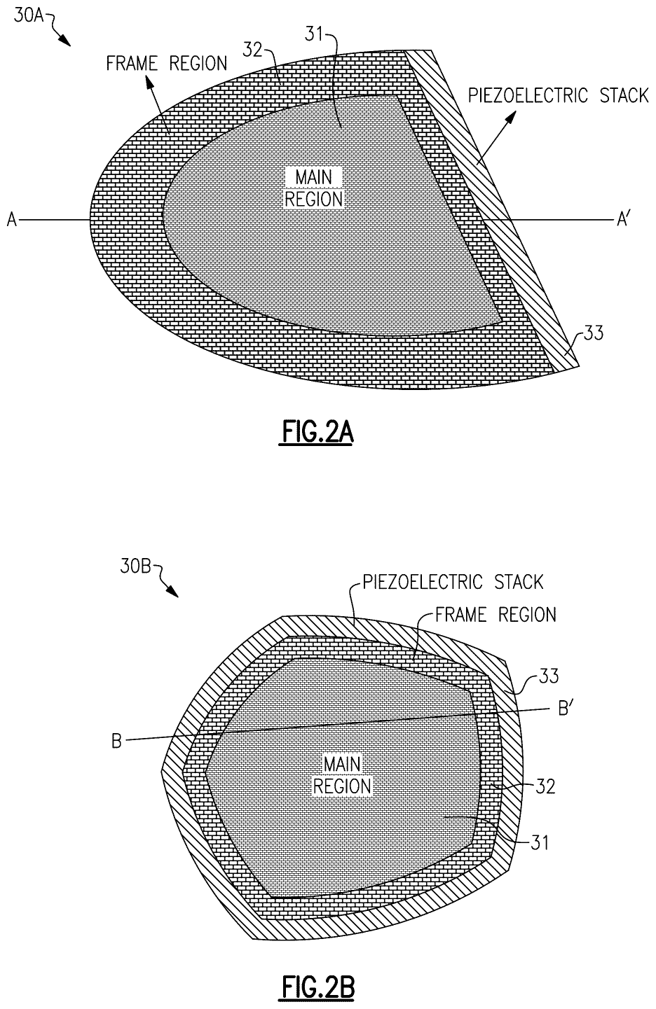

A frame region can surround the main acoustically active region of a BAW device in plan view. The main acoustically active region can be most of the area of a BAW device. The relative sizes of the main region and the frame region shown in FIGS. 2A and 2B are closer to the actual relative sizes than shown in FIG. 1. FIG. 2A shows an example frame region 32 surrounding a main acoustically active region 31 in plan view. These regions are shown over an electrode and piezoelectric material layer stack 33. The cross-sectional views in the drawings can be along the line A-A′ in FIG. 2A in certain embodiments. A BAW device 30A shown in FIG. 2A has a semi-circular or semi-elliptical shape in plan view. The electrode and piezoelectric material layer stack 33 includes at least two piezoelectric material layers and at least one interposing piezoelectric material layer or intermediate electrode in accordance with any suitable principles and advantages disclosed herein. The frame region 32 can include one or more raised frame regions and/or one or more recessed framed regions.

A BAW device in accordance with any suitable principles and advantages disclosed herein can alternatively have any other suitable shape in plan view, such as a quadrilateral shape, a quadrilateral shape with curved sides, a pentagon shape, a pentagon shape with curved sides, or the like. For example, FIG. 2B shows another example of another BAW device 30B with a frame region 32 surrounding a main acoustically active region 31 in plan view. The BAW device 30B shown in FIG. 2B has a pentagon shape with rounded sides in plan view. The cross-sectional views in the drawings can be along the line B-B′ in FIG. 2B in certain embodiments. The electrode and piezoelectric material stack 33 includes at least two piezoelectric material layers and at least one interposing piezoelectric material layer or intermediate electrode in accordance with any suitable principles and advantages disclosed herein. The frame region 32 shown in FIG. 2B can include one or more raised frame regions and/or one or more recessed framed regions.

FIG. 3 is a cross sectional schematic diagram of a portion of the electrode and piezoelectric material layer stack 15 of the BAW device 10 of FIG. 1. FIG. 3 illustrates the electrodes 26 and 28, the piezoelectric material layers 22 and 24, and the at least one interposing piezoelectric material layer or intermediate electrode 23 in a main acoustically active region of the BAW device 10. In the electrode and piezoelectric material stack 15, the interposing piezoelectric material layer or intermediate electrode 23 is sandwiched between the piezoelectric material layers 22 and 24 which are, in turn, are stacked with each other and sandwiched between the first electrode 26 and the second electrode 28. In the electrode and piezoelectric material layer stack 15, the layers 22, 23, and 24 are acoustically coupled with each other.

The piezoelectric material layers 22 and 24 can be formed by sputtering, such as physical vapor deposition (PVD) sputtering, or by atomic layer deposition (ALD). The piezoelectric material layers 22 and 24 can be aluminum nitride (AlN) layers. The piezoelectric material layers 22 and 24 can be aluminum nitride (AlN) layers doped with scandium (Sc), yttrium (Y), hafnium (Hf), zirconium (Zr), titanium (Ti), magnesium (Mg), chromium (Cr), or boron (B). The piezoelectric material layers 22 and 24 can be aluminum nitride (AlN) layers doped with at least 15 atomic percent of scandium (Sc). In some implementations, for example, the Sc content of the piezoelectric material layers 22 and 24 can be about 20 atomic percent.

Due to the material of the first electrode 26 and the second electrode 28, the piezoelectric material layers 22 and 24 can have a first polarization. The polarity of a piezoelectric material layer can be characterized by the sign of the piezoelectric material responses (values of d₃₃). Positive d₃₃ indicates that the polarity of an AlN-based thin film is predominantly oriented toward the substrate, i.e., having Al-polarity. On the other hand, negative d₃₃ indicates that the polarity of an AlN-based thin film is predominantly oriented away from the substrate, i.e., having N-polarity. The first polarization can be an Al-type polarization. Al-type polarization is where an aluminum layer is first for an AlN layer. An AlN piezoelectric material layer with Al-type polarization can be referred to as being Al-polar. In alternative implementations, the first polarization can be an N-type polarization. N-type polarization is where a nitrogen layer is first for an AlN layer. An AlN piezoelectric material layer with N-type polarization can be referred to as being N-polar.

The intermediate layer 23 can be a piezoelectric material layer. For example, the intermediate layer 23 can be an AlN layer. The intermediate AlN layer 23 can be doped with scandium (Sc), yttrium (Y), hafnium (Hf), zirconium (Zr), titanium (Ti), magnesium (Mg), chromium (Cr), or boron (B). The intermediate AlN layer 23 can be doped with at least 15 atomic percent of scandium (Sc). In some implementations, for example, the Sc content of the intermediate AlN layer 23 can be about 20 atomic percent. The intermediate AlN layer 23 can have a second polarization. The second polarization can be of the opposite polarity to the first polarization. In some implementations, when the first polarization is an Al-type polarization, the second polarization is an N-type polarization. In alternative implementations, when the first polarization is an N-type polarization, the second polarization is an Al-type polarization.

Any of the AlN piezoelectric material layers 22, 23, and 24 can be doped or undoped. Piezoelectric material layers deposited by ALD that include AlN can also include one or more additional elements, such as a dopant and/or oxygen, in certain implementations. An Al(Sc)N piezoelectric material layer can be deposited by ALD using a scandium precursor. An AlON film can be deposited by ALD with a variety of oxygen to nitrogen ratios. In certain implementations, an Al(Sc)ON piezoelectric material can be deposited by ALD. The piezoelectric material layers deposited by ALD disclosed herein can include one or more additional elements other than aluminum and nitrogen as suitable.

The piezoelectric material layers 22, 23, and 24 can each include a same piezoelectric material. The piezoelectric material layers 22, 23, and 24 can include any suitable piezoelectric material. For example, the piezoelectric material layers 22, 23, and 24 can include zinc oxide (ZnO). As another example, the piezoelectric material layers 22, 23, and 24 can include gallium nitride (GaN), or indium nitride (InN). Sputtered piezoelectric material layers can be doped in certain embodiments. The piezoelectric material layer 22 can have approximately the same thickness as the piezoelectric material layer 24 in certain embodiments. The piezoelectric material layers 22 and 24 can have any suitable relative thicknesses for a particular implementation.

In other implementations, the intermediate layer can be an intermediate or interposer electrode 23. For the purposes of inverting the piezoelectric polarity the interposer electrode 23 promotes the desired polarity in the adjacent piezoelectric material layers 22 and 24. For example, the interposer electrode 23 may include ruthenium (Ru). Sputtering an AlN piezoelectric material layer on a Ru interposer electrode 23 results in an N-polar piezoelectric material layer. In other implementations, the interposer electrode 23 may include molybdenum (Mo), tungsten (W), chromium (Cr), iridium (Ir), platinum (Pt), Ir/Pt, nickel (Ni), cobalt (Co), or any suitable alloy and/or combination thereof. Some of those electrode materials may promote the formation of an Al-polar piezoelectric material layer adjacent to the respective interposer electrode 23.

The first electrode 26 can be referred to as a lower electrode. The first electrode 26 can have a relatively high acoustic impedance. The first electrode 26 can include molybdenum (Mo), tungsten (W), ruthenium (Ru), iridium (Ir), platinum (Pt), osmium (Os), rhenium (Re), aluminum (Al), beryllium (Be), or titanium (Ti). In other implementations, the first electrode 26 can include chromium (Cr), iridium (Ir), platinum (Pt), Ir/Pt, nickel (Ni), cobalt (Co), or any suitable alloy and/or combination thereof. Similarly, the second electrode 28 can have a relatively high acoustic impedance. The second electrode 28 can include Mo, W, Ru, Ir, Pt, Os, Re, Al, Be, or Ti. In other implementations, the second electrode 28 can include Cr, Ir, Pt, Ir/Pt, Ni, Co, or any suitable alloy and/or combination thereof. The second electrode 28 can be formed of the same material as the first electrode 26 in certain instances. The second electrode 28 can be referred to as an upper electrode. The thickness of the first electrode 26 can be approximately the same as the thickness of the second electrode 28 in the electrode and piezoelectric material layer stack 15. The interposer electrode 23 can have a thickness that is larger than the thickness of the first electrode 26 and the second electrode 28. More particularly, in some implementations, the interposer electrode 23 can have a thickness that is at least twice as large as the thickness of the first electrode 26 and the second electrode 28.

The arrangement of the stacked piezoelectric material layers 22 and 24 along with the interposing piezoelectric material layer or intermediate electrode 23 can excite a second harmonic mode as a main mode for the BAW device 10, i.e., the third tone of the odd over-moded BAW device 10. The second harmonic mode has a resonant frequency that can be about twice the resonant frequency of a fundamental mode of the BAW device 10. However, the frequency value of the resonant frequency for the second harmonic mode may not be exactly twice the value of a resonant frequency of the fundamental mode, for example, due to contributions of the electrodes 26 and 28 of the BAW device 10 to the resonant frequency.

Other embodiments of piezoelectric material and electrode stacks of odd over-moded BAW devices with at least two stacked piezoelectric material layers and an intermediate polarity inverting layer will be discussed with reference to example cross-sections shown in FIGS. 4 to 7. These electrode and piezoelectric material layer stacks can be implemented in place of the electrode and piezoelectric material layer stack 15 of FIGS. 1 and 3. These electrode and piezoelectric material layer stacks can be implemented in any other suitable BAW device. Any suitable combination of features of the electrode and piezoelectric material layer stacks of FIGS. 3 to 7 can be combined with each other.

FIG. 4 is a cross-sectional diagram of a portion of the electrode and piezoelectric material layer stack 40 of an odd over-moded BAW device. For example, the electrode and piezoelectric material layer stack 40 may be implemented in the BAW device 10 of FIG. 1, replacing the electrode and piezoelectric material stack 15 of FIG. 3. The electrode and piezoelectric material layer stack 40 of FIG. 4 is similar to the electrode and piezoelectric material layer stack 15 of FIG. 3, except that the intermediate layer 23 is replaced by an intermediate electrode and piezoelectric material layer stack 48. The intermediate electrode and piezoelectric material layer stack 48 acts as an interposer sandwiched between the piezoelectric material layers 22 and 24, and includes a first intermediate electrode 42, a second intermediate electrode 46, and a second piezoelectric material layer 44. The second piezoelectric material layer 44 is sandwiched between the first intermediate electrode 42 and the second intermediate electrode 46. The first intermediate electrode 42 and the second intermediate electrode 46 may, for example, be Ru, Mo, W, Ir, Pt, Os, Re, Al, Be, or Ti electrodes.

The second piezoelectric material layer 44 can be of a polarity type opposite to the polarity type of the at least two first piezoelectric material layers 22 and 24. For example, if the at least two first piezoelectric material layers 22 and 24 and the second piezoelectric material layer 44 include aluminum nitride (AlN) layers, the two first piezoelectric material layers 22 and 24 can be Al-polar and second piezoelectric material layer 44 can be N-polar, or vice versa.

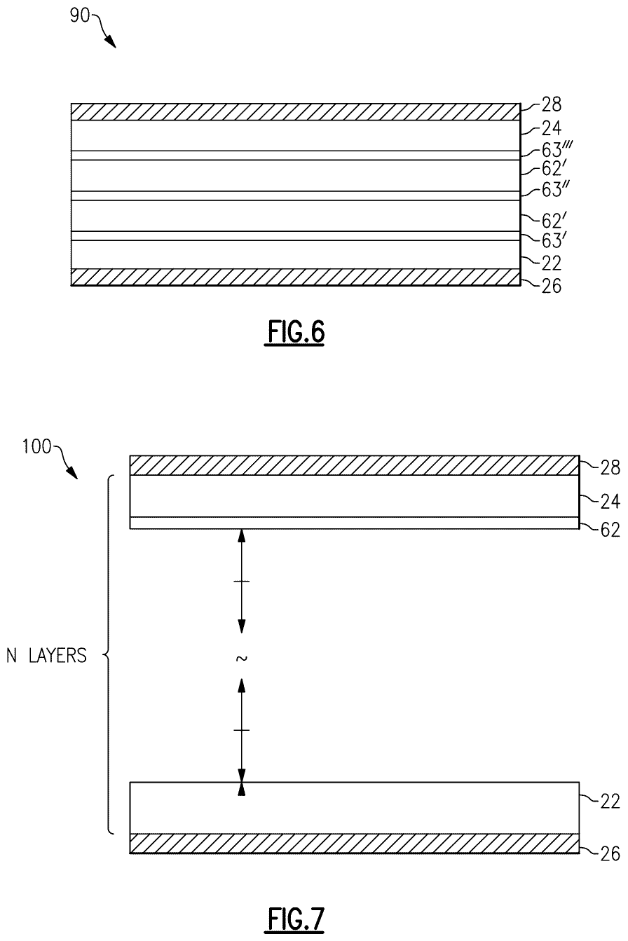

FIG. 5 is a cross-sectional diagram of a portion of the electrode and piezoelectric material layer stack 50 of an odd over-moded BAW device. For example, the electrode and piezoelectric material layer stack 50 may be implemented in the BAW device 10 of FIG. 1, replacing the electrode and piezoelectric material layer stack 15 of FIG. 3. The electrode and piezoelectric material layer stack 50 of FIG. 5 is similar to the electrode and piezoelectric material layer stack 40 of FIG. 4, except that the intermediate layer stack 58 does not have a second piezoelectric material layer 44, but a temperature compensation layer 54 sandwiched between the first intermediate electrode 42 and the second intermediate electrode 46 and is thus an intermediate electrode and temperature compensation material layer stack. The intermediate electrode and temperature compensation material layer stack 58 acts as an interposer sandwiched between the piezoelectric material layers 22 and 24. The temperature compensation layer 54 can be utilized to achieve a much better temperature coefficient of frequency (TCF) for a BAW device than for a similar BAW device in which a temperature compensation layer is deposited on top of the electrode and piezoelectric material layer stack. The downside of the provision of the temperature compensation layer 54 is the slightly increased impedance of the overall stack resulting in a decrease in electromechanical coupling, however, the improvement in TCF is specifically beneficial in BAW devices where the piezoelectric material layers 22 and 24 are manufactured as AlN layers doped with a higher amount of Sc.

FIG. 6 is a cross-sectional diagram of a portion of the electrode and piezoelectric material layer stack 90 of an odd over-moded BAW device. For example, the electrode and piezoelectric material layer stack 90 may be implemented in the BAW device 10 of FIG. 1, replacing the electrode and piezoelectric material layer stack 15 of FIG. 3. The electrode and piezoelectric material layer stack 90 of FIG. 6 is similar to the electrode and piezoelectric material layer stack 15 of FIG. 3, except that the electrode and piezoelectric material layer stack 90 includes at least three piezoelectric material layers of the same polarity sandwiched between the first electrode and the second electrode. The at least three first piezoelectric material layers include AlN layers. In the example illustrated in FIG. 6, the electrode and piezoelectric material stack 90 includes the top piezoelectric material layer 24, the bottom piezoelectric material layer 22, and two more middle piezoelectric material layers 62′, all of which have the same polarity, for example, Al-polar or N-polar. A first interposer 63′″ is sandwiched between the top piezoelectric material layer 24 and a first one of the middle piezoelectric material layers 62′. A second interposer 63′″ is sandwiched between the first one of the middle piezoelectric material layers 62′ and a second one of the middle piezoelectric material layers 62′. A third interposer 63′ is sandwiched between the second one of the middle piezoelectric material layers 62′ and the bottom piezoelectric material layer 22.

The interposers 63′, 63′″, 63′″ can be intermediate electrodes, having the same properties and characteristics as the intermediate electrode 23 of the electrode and piezoelectric material layer stack 15 illustrated in FIG. 3. In other implementations, the interposers 63′, 63″, 63′″ can be intermediate electrode and piezoelectric material layer stacks, having the same properties and characteristics as the intermediate electrode and piezoelectric material layer stack 48 as illustrated in FIG. 4 or as the intermediate electrode and temperature compensation material layer stack 58 as illustrated in FIG. 5.

A BAW device including the electrode and piezoelectric material layer stack 90 of FIG. 6 can excite a sixth harmonic mode as a main mode for the BAW device, i.e., the seventh tone of an odd over-moded BAW device.

FIG. 7 illustrates a generalized electrode and piezoelectric material layer stack 100 that can be implemented in any of the BAW devices and BAW resonators as disclosed herein. The electrode and piezoelectric material layer stack 100 includes a first electrode 26, a second electrode 28, a first piezoelectric material layer 24, a second piezoelectric material layer 22, and an intermediate electrode and piezoelectric material layer stack including a number of N−1 layers of alternating piezoelectric material layers and interposers 62. The number N indicates the harmonic mode on which the respective BAW device operates on as a main mode.

Any suitable principles and advantages disclosed herein can be applied to floating raised frame structures where a raised frame structure is at a floating voltage level. The floating raised frame structure can be electrically isolated from the electrodes of the BAW device (e.g., by a dielectric material).

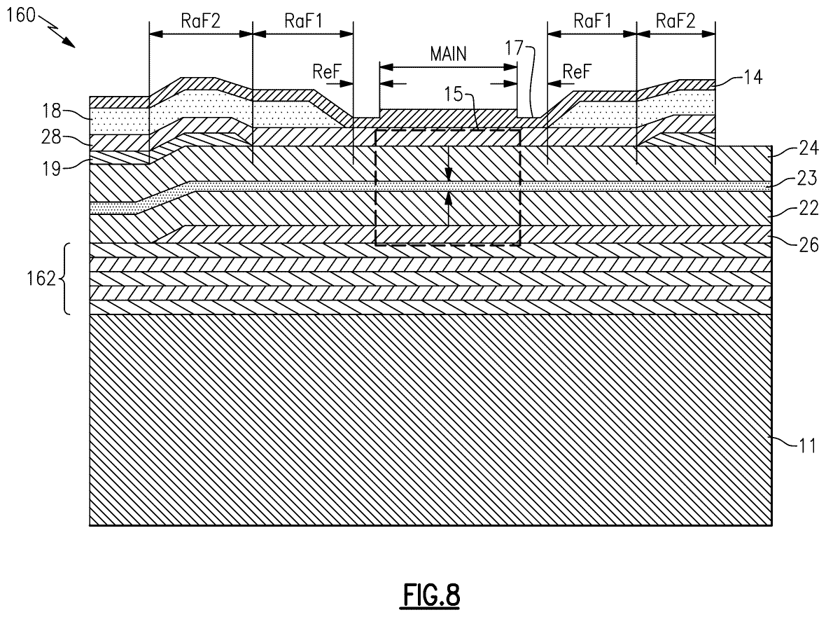

The BAW devices 10, 15, 30A, 30B, 40, 50, 90, and 100 of FIGS. 1, 2A, 2B, 3, 4, 5, 6, and 7 are examples of film bulk acoustic wave resonators. Any suitable principles and advantages disclosed herein can be applied to other BAW devices. FIG. 8 illustrates a BAW solidly mounted resonator (BAW-SMR) 160 with a dual gradient raised frame structure. The BAW-SMR 160 includes a solid acoustic mirror 162 positioned over a support substrate 11 in place of an air cavity as an acoustic reflector below a lower electrode 26. Any suitable principles and advantages disclosed herein can be applied to SMRs.

BAW devices can include a multi-layer raised frame structure with a plurality of gradients. The multi-layer raised frame structure can include a first raised frame layer positioned between a lower electrode and an upper electrode of a BAW device. The multi-layer raised frame structure can also include a second raised frame layer positioned over the first raised frame layer. The second raised frame layer can extend beyond the first raised frame layer. The second raised frame layer can be tapered on opposing sides where the second raised frame layer extends beyond the first raised frame layer. Tapered portions of the second raised frame layer can have a taper angle that is less than 90 degrees. The multi-layer raised frame structure can have a convex structure relative to a surface of a piezoelectric material layer and/or an electrode layer. The multi-layer raised frame structure can form a dome shaped structure. The multi-layer raised frame structure can surround a main acoustically active region of a BAW acoustic wave device in a plan view.

A gradient portion of a raised frame layer can have a taper angle α with respect to a horizontal direction in the illustrated schematic cross-sectional views. The taper angle α can be with respect to an underlying layer (e.g., a piezoelectric material layer). The taper angle α can be less than 90°. In some applications, the taper angle can be less than 40° for a gradient portion of a raised frame layer in a gradient region. In some instances, the taper angle can be in a range from about 10° to 30° for a gradient portion of a raised frame layer in a gradient region.

BAW devices disclosed herein can be implemented in acoustic wave filters. In certain embodiments, the acoustic wave filters can be band pass filters arranged to pass a radio frequency band and attenuate frequencies outside of the radio frequency band. Acoustic wave filters can implement band rejection filters. Two or more acoustic wave filters can be coupled together at a common node and arranged as a multiplexer, such as a duplexer. Example filter topologies include a ladder filter, a lattice filter, and a hybrid ladder lattice filter, and the like. An acoustic wave filter can include all BAW devices or one or more BAW devices and one or more other types of acoustic wave resonators such as a SAW resonator. BAW devices disclosed herein can be implemented in a filter that includes at least one BAW device and a non-acoustic inductor-capacitor component.

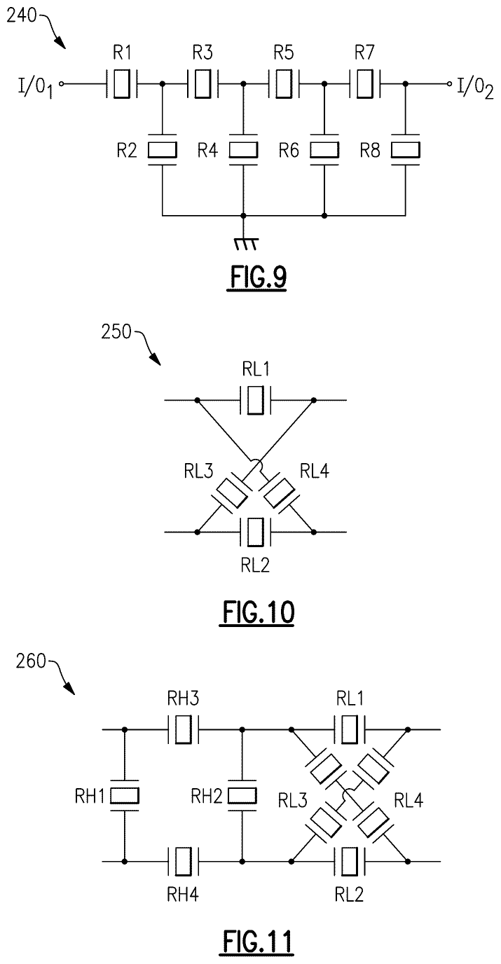

FIG. 9 is a schematic diagram of a ladder filter 240 according to an embodiment. The ladder filter 240 includes shunt BAW resonators and series BAW resonators coupled between RF input/output ports I/O₁ and I/O₂. The ladder filter 240 is an example topology of a band pass filter formed from acoustic resonators. In a band pass filter with a ladder filter topology, the shunt resonators can have lower resonant frequencies than the series resonators. The ladder filter 240 can be arranged to filter an RF signal. As illustrated, the series BAW resonators include resonators R1, R3, R5, and R7. The illustrated shunt BAW resonators include resonators R2, R4, R6, and R8. The first RF input/output port I/O₁ can be a transmit port for a transmit filter or a receive port for a receive filter. The second RF input/output port I/O₂ can be an antenna port. Any suitable number of series acoustic resonators can be included in a ladder filter. Any suitable number of shunt acoustic wave resonators can be included in a ladder filter.

In a band rejection filter, the resonators R2, R4, R6, and R8 can include at least one first type of BAW resonator having one or more electrodes manufactured from a first type of material having a low resistivity, a high elastic modulus and a low density as disclosed herein and the resonators R1, R3, R5, and R7 can include at least one second type of BAW resonator having one or more electrodes manufactured from a second type of material, different from the first type of material. In a band pass filter, the resonators R1, R3, R5, and R7 can include at least one first type of BAW resonator, and the resonators R2, R4, R6, and R8 can include at least one second type of BAW resonator.

The resonators of the first type can be BAW resonators having one or more electrodes manufactured from a first type of material and the resonators of the second type can be BAW resonators having one or more electrodes manufactured from a second type of material, different from the first type of material. Accordingly, the ladder filter 240 can include series BAW resonators and shunt BAW resonators in certain embodiments. Such BAW resonators can include film bulk acoustic wave resonators and/or solidly mounted resonators (SMRs).

FIG. 10 is a schematic diagram of a lattice filter 250 that includes one or more BAW resonators according to an embodiment. The lattice filter 250 is an example topology that can form a band pass filter from acoustic wave resonators. The lattice filter 250 can be arranged to filter an RF signal. As illustrated, the lattice filter 250 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 250 has a balanced input and a balanced output. One or more of the illustrated acoustic wave resonators RL1 to RL4 can be a BAW resonator in accordance with any suitable principles and advantages disclosed herein.

FIG. 11 is a schematic diagram of a hybrid ladder and lattice filter 260 that includes one or more BAW resonators according to an embodiment. The illustrated hybrid ladder and lattice filter 260 includes series acoustic resonators RL1, RL2, RH3, and RH4 and shunt acoustic resonators RL3, RL4, RH1, and RH2. The hybrid ladder and lattice filter 260 includes one or more BAW resonators in accordance with any suitable principles and advantages disclosed herein.

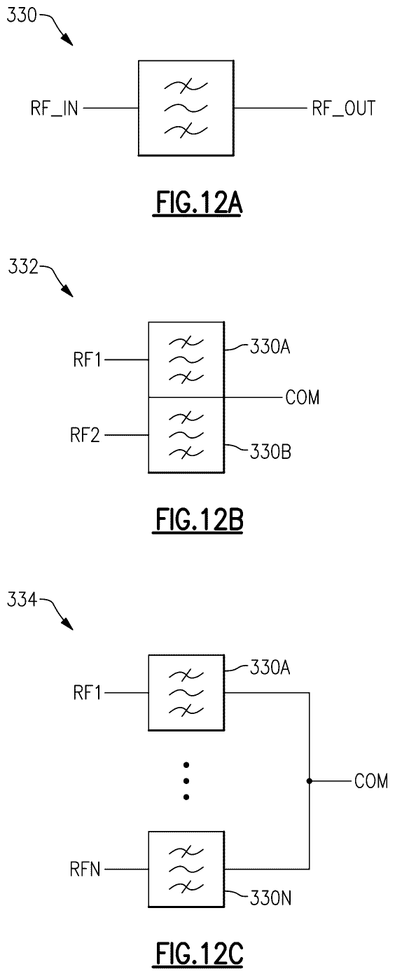

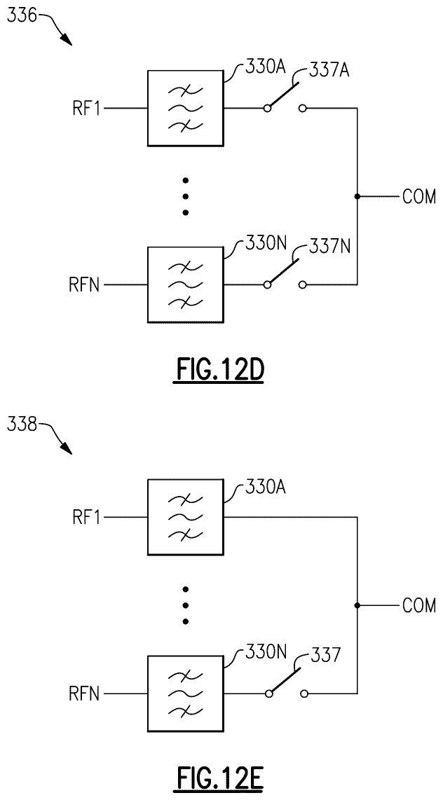

The principles and advantages disclosed herein can be implemented in a standalone filter and/or in one or more filters in any suitable multiplexer. Such filters can be any suitable topology discussed herein, such as any filter topology in accordance with any suitable principles and advantages disclosed with reference to FIGS. 1, 2A, 2B, 3, 4, 5, 6, 7, and 8. The filter can be a band pass filter arranged to filter a fourth generation (4G) Long Term Evolution (LTE) band and/or a fifth generation (5G) New Radio (NR) band. Examples of a standalone filter and multiplexers will be discussed with reference to FIGS. 12A to 12E. Any suitable principles and advantages of these filters and/or multiplexers can be implemented together with each other. Moreover, the BAW resonators disclosed herein can be included in filters that also include one or more inductors and/or one or more capacitors.

FIG. 12A is schematic diagram of an acoustic wave filter 330. The acoustic wave filter 330 is a band pass filter. The acoustic wave filter 330 is arranged to filter a radio frequency signal. The acoustic wave filter 330 includes a plurality of acoustic wave resonators coupled between a first input/output port RF_IN and a second input/output port RF_OUT. The acoustic wave filter 330 includes one or more BAW resonators implemented in accordance with any suitable principles and advantages disclosed herein.

FIG. 12B is a schematic diagram of a duplexer 332 that includes an acoustic wave filter according to an embodiment. The duplexer 332 includes a first filter 330A and a second filter 330B coupled together at a common node COM. One of the filters of the duplexer 332 can be a transmit filter and the other of the filters of the duplexer 332 can be a receive filter. In some other instances, such as in a diversity receive application, the duplexer 332 can include two receive filters. Alternatively, the duplexer 332 can include two transmit filters. The common node COM can be an antenna node.

The first filter 330A is an acoustic wave filter arranged to filter a radio frequency signal. The first filter 330A includes acoustic wave resonators coupled between a first radio frequency node RF1 and the common node COM. The first radio frequency node RF1 can be a transmit node or a receive node. The first filter 330A includes one or more BAW resonators implemented in accordance with any suitable principles and advantages disclosed herein.

The second filter 330B can be any suitable filter arranged to filter a second radio frequency signal. The second filter 330B can be, for example, an acoustic wave filter that includes one or more BAW resonators in accordance with any suitable principles and advantages disclosed herein, an LC filter, a hybrid acoustic wave LC filter, or the like. The second filter 330B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implemented in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of BAW resonators in accordance with any suitable principles and advantages disclosed herein.

FIG. 12C is a schematic diagram of a multiplexer 334 that includes an acoustic wave filter according to an embodiment. The multiplexer 334 includes a plurality of filters 330A to 330N coupled together at a common node COM. The plurality of filters can include any suitable number of filters including, for example, 3 filters, 4 filters, 5 filters, 6 filters, 7 filters, 8 filters, or more filters. Some or all of the plurality of filters can be acoustic wave filters. As illustrated, the filters 330A to 330N each have a fixed electrical connection to the common node COM. This can be referred to as hard multiplexing or fixed multiplexing. Filters have fixed electrical connections to the common node in hard multiplexing applications. Each of the filters 330A to 330N has a respective input/output node RF1 to RFN.

The first filter 330A is an acoustic wave filter arranged to filter a radio frequency signal. The first filter 330A can include one or more acoustic wave devices coupled between a first radio frequency node RF1 and the common node COM. The first radio frequency node RF1 can be a transmit node or a receive node. The first filter 330A includes one or more BAW resonators in accordance with any suitable principles and advantages disclosed herein. The other filter(s) of the multiplexer 334 can include one or more acoustic wave filters, one or more acoustic wave filters that include one or more BAW resonators in accordance with any suitable principles and advantages disclosed herein, one or more LC filters, one or more hybrid acoustic wave LC filters, or any suitable combination thereof.

FIG. 12D is a schematic diagram of a multiplexer 336 that includes an acoustic wave filter according to an embodiment. The multiplexer 336 is like the multiplexer 334 of FIG. 12C, except that the multiplexer 336 implements switched multiplexing. In switched multiplexing, a filter is coupled to a common node via a switch. In the multiplexer 336, the switches 337A to 337N can selectively electrically connect respective filters 330A to 330N to the common node COM. For example, the switch 337A can selectively electrically connect the first filter 330A to the common node COM via the switch 337A. Any suitable number of the switches 337A to 337N can electrically connect respective filters 330A to 330N to the common node COM in a given state. Similarly, any suitable number of the switches 337A to 337N can electrically isolate respective filters 330A to 330N from the common node COM in a given state. The functionality of the switches 337A to 337N can support various carrier aggregations.

FIG. 12E is a schematic diagram of a multiplexer 338 that includes an acoustic wave filter according to an embodiment. The multiplexer 338 illustrates that a multiplexer can include any suitable combination of hard multiplexed and switched multiplexed filters. One or more BAW resonators in accordance with any suitable principles and advantages disclosed herein can be included in a filter that is hard multiplexed to the common node of a multiplexer. Alternatively or additionally, one or more BAW resonators in accordance with any suitable principles and advantages disclosed herein can be included in a filter that is switch multiplexed to the common node of a multiplexer.

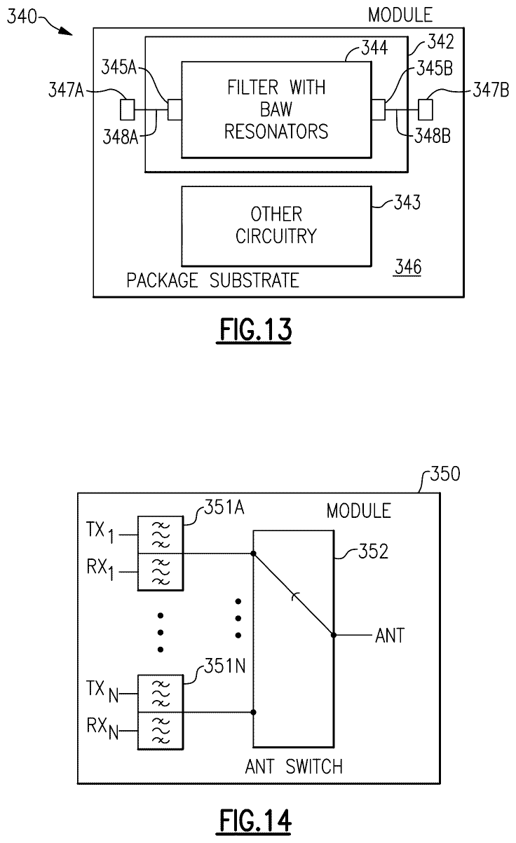

BAW resonators disclosed herein can be implemented in a variety of packaged modules. Some example packaged modules will now be discussed in which any suitable principles and advantages of the BAW devices disclosed herein can be implemented. Example packaged modules include one or more acoustic wave filters and one or more radio frequency amplifiers (e.g., one or more power amplifiers and/or one or more low noise amplifiers) and/or one or more radio frequency switches. The example packaged modules can include a package that encloses the illustrated circuit elements. The illustrated circuit elements can be disposed on a common packaging substrate. The packaging substrate can be a laminate substrate, for example. FIGS. 13 to 17 are schematic block diagrams of illustrative packaged modules according to certain embodiments. Any suitable combination of features of these packaged modules can be implemented with each other. While duplexers are illustrated in the example packaged modules of FIGS. 13 to 17, any other suitable multiplexer that includes a plurality of filters coupled to a common node can be implemented instead of one or more duplexers. For example, a quadplexer can be implemented in certain embodiments. Alternatively or additionally, one or more filters of a packaged module can be arranged as a transmit filter or a receive filter that is not included in a multiplexer.

FIG. 13 is a schematic diagram of a radio frequency module 340 that includes an acoustic wave component 342 according to an embodiment. The illustrated radio frequency module 340 includes the acoustic wave component 342 and other circuitry 343. The acoustic wave component 342 can include one or more BAW resonators in accordance with any suitable combination of features disclosed herein. The acoustic wave component 342 can include a BAW die that includes BAW resonators.

The acoustic wave component 342 shown in FIG. 13 includes a filter 344 and terminals 345A and 345B. The filter 344 includes one or more BAW resonators implemented in accordance with any suitable principles and advantages disclosed herein. The terminals 345A and 344B can serve, for example, as an input contact and an output contact. The acoustic wave component 342 and the other circuitry 343 are on a common packaging substrate 346 in FIG. 13. The packaging substrate 346 can be a laminate substrate. The terminals 345A and 345B can be electrically connected to contacts 347A and 347B, respectively, on the packaging substrate 346 by way of electrical connectors 348A and 348B, respectively. The electrical connectors 348A and 348B can be bumps or wire bonds, for example.

The other circuitry 343 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. The other circuitry 343 can be electrically connected to the filter 344. The radio frequency module 340 can include one or more packaging structures to, for example, provide protection and/or facilitate easier handling of the radio frequency module 340. Such a packaging structure can include an overmold structure formed over the packaging substrate 346. The overmold structure can encapsulate some or all of the components of the radio frequency module 340.

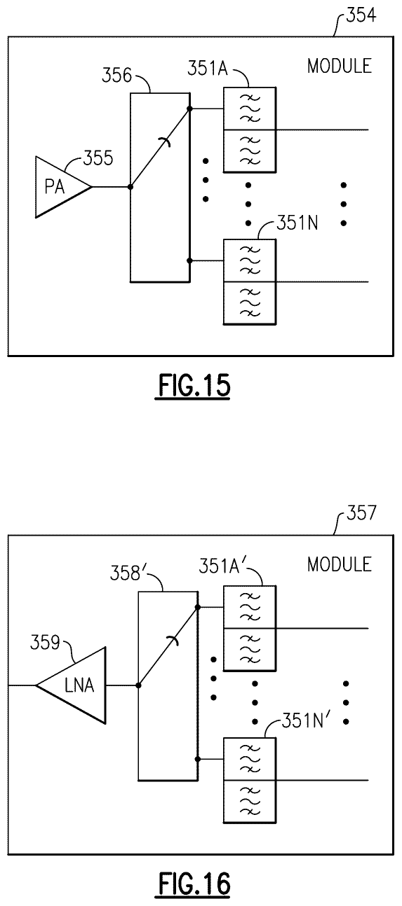

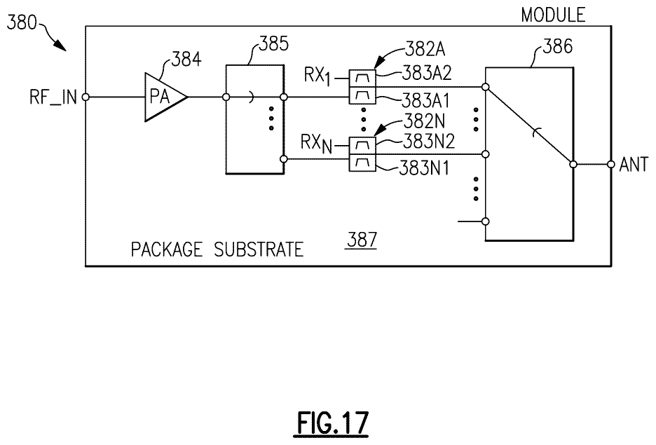

FIG. 14 is a schematic block diagram of a module 350 that includes multiplexers 351A to 351N and an antenna switch 352. One or more filters of the multiplexers 351A to 351N can include one or more BAW resonators in accordance with any suitable principles and advantages discussed herein. Any suitable number of multiplexers 351A to 351N can be implemented. The antenna switch 352 can have a number of throws corresponding to the number of multiplexers 351A to 351N. The antenna switch 352 can include one or more additional throws coupled to one or more filters external to the module 350 and/or coupled to other circuitry. The antenna switch 352 can electrically couple a selected duplexer to an antenna port of the module 350. The multiplexers 351A to 351N can include one or more duplexers.

FIG. 15 is a schematic block diagram of a module 354 that includes a power amplifier 355, a radio frequency switch 356, and multiplexers 351A to 351N in accordance with one or more embodiments. The power amplifier 355 can amplify a radio frequency signal. The radio frequency switch 356 can be a multi-throw radio frequency switch. The radio frequency switch 356 can electrically couple an output of the power amplifier 355 to a selected transmit filter of the multiplexers 351A to 351N. One or more filters of the multiplexers 351A to 351N can include any suitable number of BAW resonators in accordance with any suitable principles and advantages discussed herein. Any suitable number of multiplexers 351A to 351N can be implemented.

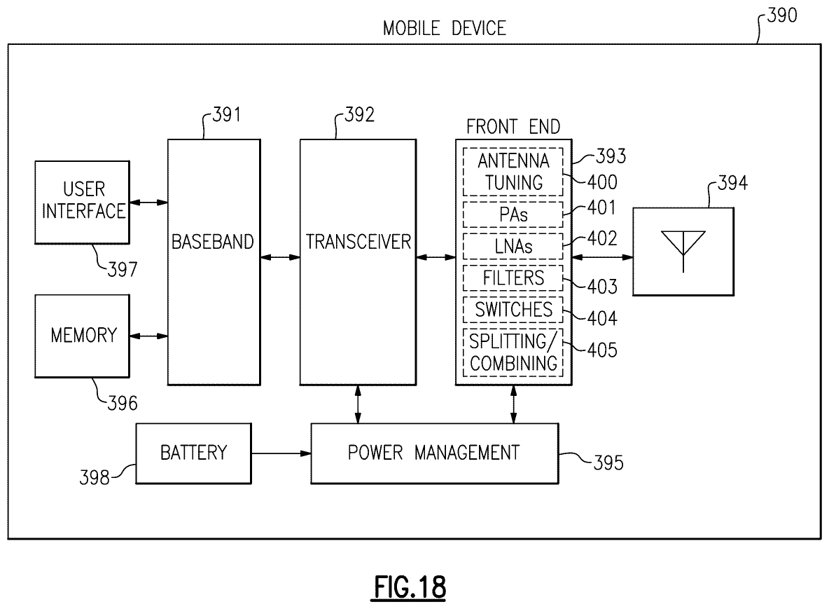

FIG. 16 is a schematic block diagram of a module 357 that includes multiplexers 351A′ to 351N′, a radio frequency switch 358′, and a low noise amplifier 359 according to an embodiment. One or more filters of the multiplexers 351A′ to 351N′ can include any suitable number BAW resonators in accordance with any suitable principles and advantages disclosed herein. Any suitable number of multiplexers 351A′ to 351N′ can be implemented. The radio frequency switch 358′ can be a multi-throw radio frequency switch. The radio frequency switch 358′ can electrically couple an output of a selected filter of multiplexers 351A′ to 351N′ to the low noise amplifier 359. In some embodiments (not illustrated), a plurality of low noise amplifiers can be implemented. The module 357 can include diversity receive features in certain applications.

FIG. 17 is a schematic diagram of a radio frequency module 380 that includes an acoustic wave filter according to an embodiment. As illustrated, the radio frequency module 380 includes duplexers 382A to 382N that include respective transmit filters 383A1 to 383N1 and respective receive filters 383A2 to 383N2, a power amplifier 384, a select switch 385, and an antenna switch 386. The radio frequency module 380 can include a package that encloses the illustrated elements. The illustrated elements can be disposed on a common packaging substrate 387. The packaging substrate 387 can be a laminate substrate, for example. A radio frequency module that includes a power amplifier can be referred to as a power amplifier module. A radio frequency module can include a subset of the elements illustrated in FIG. 17 and/or additional elements. The radio frequency module 380 may include one or more BAW resonators in accordance with any suitable principles and advantages disclosed herein.

The duplexers 382A to 382N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters 383A1 to 383N1 can include one or more BAW resonators in accordance with any suitable principles and advantages disclosed herein. Similarly, one or more of the receive filters 383A2 to 383N2 can include one or more BAW resonators in accordance with any suitable principles and advantages disclosed herein. Although FIG. 17 illustrates duplexers, any suitable principles and advantages disclosed herein can be implemented in other multiplexers (e.g., quadplexers, hexaplexers, octoplexers, etc.) and/or in switched multiplexers.

The power amplifier 384 can amplify a radio frequency signal. The illustrated switch 385 is a multi-throw radio frequency switch. The switch 385 can electrically couple an output of the power amplifier 384 to a selected transmit filter of the transmit filters 383A1 to 383N1. In some instances, the switch 385 can electrically connect the output of the power amplifier 384 to more than one of the transmit filters 383A1 to 383N1. The antenna switch 386 can selectively couple a signal from one or more of the duplexers 382A to 382N to an antenna port ANT. The duplexers 382A to 382N can be associated with different frequency bands and/or different modes of operation (e.g., different power modes, different signaling modes, etc.).

Odd over-moded BAW resonators as disclosed herein can be implemented in a variety of wireless communication devices, such as mobile devices. One or more filters with any suitable number of BAW devices implemented with any suitable principles and advantages disclosed herein can be included in a variety of wireless communication devices, such as mobile phones. The BAW devices can be included in a filter of a radio frequency front end (RFFE). FIG. 18 is a schematic diagram of one embodiment of a mobile device 390. The mobile device 390 includes a baseband system 391, a transceiver 392, a front end system 393, antennas 394, a power management system 395, a memory 396, a user interface 397, and a battery 398.

The mobile device 390 can be used communicate using a wide variety of communications technologies, including, but not limited to, second generation (2G), third generation (3G), fourth generation (4G) (including LTE, LTE-Advanced, and LTE-Advanced Pro), fifth generation (5G) New Radio (NR), wireless local area network (WLAN) (for instance, WiFi), wireless personal area network (WPAN) (for instance, Bluetooth and ZigBee), WMAN (wireless metropolitan area network) (for instance, WiMax), Global Positioning System (GPS) technologies, or any suitable combination thereof. The transceiver 392 generates RF signals for transmission and processes incoming RF signals received from the antennas 394. It will be understood that various functionalities associated with the transmission and receiving of RF signals can be achieved by one or more components that are collectively represented in FIG. 18 as the transceiver 392. In one example, separate components (for instance, separate circuits or dies) can be provided for handling certain types of RF signals.

The front end system 393 aids in conditioning signals transmitted to and/or received from the antennas 394. In the illustrated embodiment, the front end system 393 includes antenna tuning circuitry 400, power amplifiers (PAs) 401, low noise amplifiers (LNAs) 402, filters 403, switches 404, and signal splitting/combining circuitry 405. However, other implementations are possible. One or more of the filters 403 can be implemented in accordance with any suitable principles and advantages disclosed herein. For example, one or more of the filters 403 can include at least one odd over-moded BAW resonator in accordance with any suitable principles and advantages disclosed herein.

For example, the front end system 393 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, duplexing or triplexing), or any suitable combination thereof.

In certain implementations, the mobile device 390 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 394 can include antennas used for a wide variety of types of communications. For example, the antennas 394 can include antennas for transmitting and/or receiving signals associated with a wide variety of frequencies and communications standards. In certain implementations, the antennas 394 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 390 can operate with beamforming in certain implementations. For example, the front end system 393 can include amplifiers having controllable gain and phase shifters having controllable phase to provide beam formation and directivity for transmission and/or reception of signals using the antennas 394. For example, in the context of signal transmission, the amplitude and phases of the transmit signals provided to the antennas 394 are controlled such that radiated signals from the antennas 394 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 394 from a particular direction. In certain implementations, the antennas 394 include one or more arrays of antenna elements to enhance beamforming.

The baseband system 391 is coupled to the user interface 397 to facilitate processing of various user input and output (I/O), such as voice and data. The baseband system 391 provides the transceiver 392 with digital representations of transmit signals, which the transceiver 392 processes to generate RF signals for transmission. The baseband system 391 also processes digital representations of received signals provided by the transceiver 392. As shown in FIG. 18, the baseband system 391 is coupled to the memory 396 to facilitate operation of the mobile device 390. The memory 396 can be used for a wide variety of purposes, such as storing data and/or instructions to facilitate the operation of the mobile device 390 and/or to provide storage of user information.

The power management system 395 provides a number of power management functions of the mobile device 390. In certain implementations, the power management system 395 includes a PA supply control circuit that controls the supply voltages of the power amplifiers 401. For example, the power management system 395 can be configured to change the supply voltage(s) provided to one or more of the power amplifiers 401 to improve efficiency, such as power added efficiency (PAE). As shown in FIG. 18, the power management system 395 receives a battery voltage from the battery 398. The battery 398 can be any suitable battery for use in the mobile device 390, including, for example, a lithium-ion battery.

The teachings herein are applicable to a wide variety of communication systems, including, but not limited to, communication systems using advanced cellular technologies, such as LTE-Advanced, LTE-Advanced Pro, and/or 5G NR. An acoustic wave device including any suitable combination of features disclosed herein be included in a filter arranged to filter a radio frequency signal in a 5G NR operating band within Frequency Range 1 (FR1). A filter arranged to filter a radio frequency signal in a 5G NR operating band can include one or more BAW devices disclosed herein. FR1 can be from 410 MHz to 7.125 GHz, for example, as specified in a current 5G NR specification. One or more BAW devices in accordance with any suitable principles and advantages disclosed herein can be included in a filter arranged to filter a radio frequency signal in a fourth generation (4G) Long Term Evolution (LTE). One or more BAW devices in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio Dual Connectivity (ENDC) application.

BAW devices disclosed herein can provide high resonant frequencies and/or desirable power ruggedness. Such features can be advantageous in 5G NR applications. For example, such filters can filter RF signals within high frequency bands. At the same time, the filters can have desirable power ruggedness for meeting 5G performance specifications at the filter level and/or at the system level.

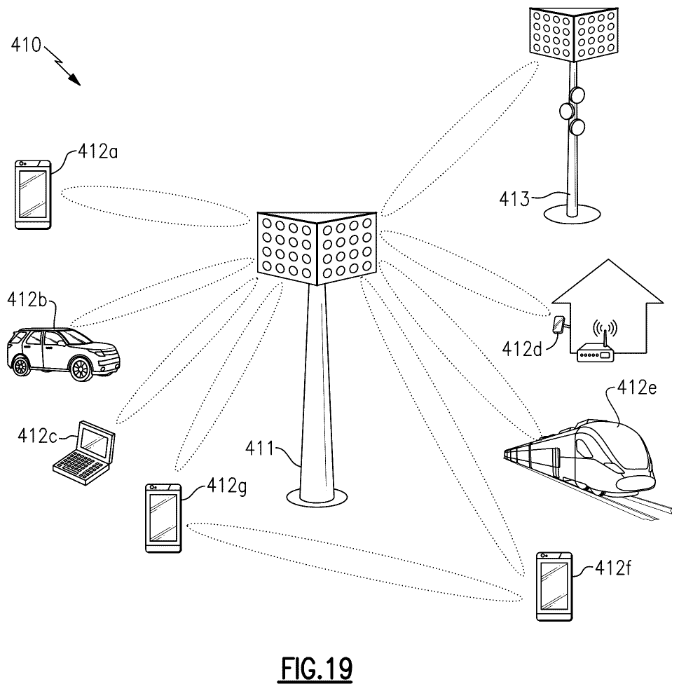

FIG. 19 is a schematic diagram of one example of a communication network 410. The communication network 410 includes a macro cell base station 411, a small cell base station 413, and various examples of user equipment (UE), including a first mobile device 412a, a wireless-connected car 412b, a laptop 412c, a stationary wireless device 412d, a wireless-connected train 412e, a second mobile device 412f, and a third mobile device 412g. UEs are wireless communication devices. One or more of the macro cell base station 411, the small cell base station 413, or UEs illustrated in FIG. 19 can implement one or more of the acoustic wave filters in accordance with any suitable principles and advantages disclosed herein. For example, one or more of the UEs shown in FIG. 19 can include one or more acoustic wave filters that include any suitable number of BAW resonators in accordance with any suitable principles and advantages disclosed herein.

Although specific examples of base stations and user equipment are illustrated in FIG. 19, a communication network can include base stations and user equipment of a wide variety of types and/or numbers. For instance, in the example shown, the communication network 410 includes the macro cell base station 411 and the small cell base station 413. The small cell base station 413 can operate with relatively lower power, shorter range, and/or with fewer concurrent users relative to the macro cell base station 411. The small cell base station 413 can also be referred to as a femtocell, a picocell, or a microcell. Although the communication network 410 is illustrated as including two base stations, the communication network 410 can be implemented to include more or fewer base stations and/or base stations of other types.

Although various examples of user equipment are shown, the teachings herein are applicable to a wide variety of user equipment, including, but not limited to, mobile phones, tablets, laptops, Internet of Things (IoT) devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 410 of FIG. 19 supports communications using a variety of cellular technologies, including, for example, 4G LTE and 5G NR. In certain implementations, the communication network 410 is further adapted to provide a wireless local area network (WLAN), such as WiFi. Although various examples of communication technologies have been provided, the communication network 410 can be adapted to support a wide variety of communication technologies.

Various communication links of the communication network 410 have been depicted in FIG. 19. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 19, the communication links include not only communication links between UE and base stations, but also UE to UE communications and base station to base station communications. For example, the communication network 410 can be implemented to support self-fronthaul and/or self-backhaul (for instance, as between mobile device 412g and mobile device 412f).

The communication links can operate over a wide variety of frequencies. In certain implementations, communications are supported using 5G NR technology over one or more frequency bands that are less than 6 GHz and/or over one or more frequency bands that are greater than 6 GHz. According to certain implementations, the communication links can serve Frequency Range 1 (FR1), Frequency Range 2 (FR2), or a combination thereof. An acoustic wave filter in accordance with any suitable principles and advantages disclosed herein can filter a radio frequency signal within FR1. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 410 can share available network resources, such as available frequency spectrum, in a wide variety of ways. In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 3 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 410 of FIG. 19 can be used to support a wide variety of advanced communication features, including, but not limited to, eMBB, uRLLC, and/or mMTC.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can range from 410 megahertz (MHz) to 7.125 gigahertz (GHz), for example, as specified in a current 5G NR specification. A filter arranged to filter a radio frequency signal in a 5G NR FR1 operating band can include one or more odd over-moded BAW resonators implemented in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smartphone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including,” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled,” as generally used herein, refers to two or more elements that may be either directly coupled, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave (BAW) device comprising:
a first electrode;
a second electrode;
a stack of at least two first piezoelectric material layers of a same polarity type sandwiched between the first electrode and the second electrode; and
a first interposer sandwiched between the at least two first piezoelectric material layers and including at least one intermediate electrode, the BAW device being configured to excite an even overtone mode as a main mode of operation.

2. The BAW device of claim 1 further comprising a raised frame structure within a raised frame domain outside of a middle area of an active region of the BAW device, the raised frame structure including a first raised frame layer positioned between one of the first and second electrodes and the at least two first piezoelectric material layers, the first raised frame layer having a lower acoustic impedance than the first or second electrode and a lower acoustic impedance than the at least two first piezoelectric material layers.

3. The BAW device of claim 2 further comprising a recessed frame domain between the raised frame domain and the middle area.

4. The BAW device of claim 1 wherein the first interposer includes a first intermediate electrode, a second intermediate electrode, and a second piezoelectric material layer sandwiched between the first intermediate electrode and the second intermediate electrode.

5. The BAW device of claim 4 wherein the second piezoelectric material layer is of a polarity type opposite to the polarity type of the at least two first piezoelectric material layers.

6. The BAW device of claim 5 wherein the at least two first piezoelectric material layers and the second piezoelectric material layer include aluminum nitride (AlN) layers.

7. The BAW device of claim 6 wherein the polarity type of the at least two first piezoelectric material layers is Al-polar and the polarity type of the second piezoelectric material layer is N-polar.

8. The BAW device of claim 6 wherein the polarity type of the at least two first piezoelectric material layers is N-polar and the polarity type of the second piezoelectric material layer is Al-polar.

9. The BAW device of claim 1 wherein the stack of at least two first piezoelectric material layers of the same polarity type includes at least three first piezoelectric material layers sandwiched between the first electrode and the second electrode.

10. The BAW device of claim 9 wherein the first interposer is sandwiched between a first one and a second one of the at least three first piezoelectric material layers.

11. The BAW device of claim 10 further comprising a second interposer sandwiched between the second one and a third one of the at least three first piezoelectric material layers.

12. The BAW device of claim 1 wherein the first interposer includes a first intermediate electrode, a second intermediate electrode, and a temperature compensation layer sandwiched between the first intermediate electrode and the second intermediate electrode.

13. The BAW device of claim 4 wherein a thickness of the first intermediate electrode and the second intermediate electrode of the first interposer is larger than a thickness of the first electrode and the second electrode.

14. The BAW device of claim 13 wherein the thickness of the first intermediate electrode and the second intermediate electrode of the first interposer is at least twice as large as the thickness of the first electrode and the second electrode.

15. A film bulk acoustic wave resonator device comprising:
a substrate;
first and second conductive layers implemented over the substrate;
a stack of at least two first piezoelectric material layers of a same polarity type sandwiched between the first conductive layer and the second conductive layer; and
a first interposer sandwiched between the at least two first piezoelectric material layers and having at least one intermediate conductive layer, the film bulk acoustic wave resonator device being configured to excite an even overtone mode as a main mode of operation.

16. The film bulk acoustic wave resonator device of claim 15 wherein the first interposer includes a first intermediate conductive layer, a second intermediate conductive layer, and a second piezoelectric material layer sandwiched between the first intermediate conductive layer and the second intermediate conductive layer.

17. The film bulk acoustic wave resonator device of claim 16 wherein the second piezoelectric material layer is of a polarity type opposite to the polarity type of the at least two first piezoelectric material layers.

18. The film bulk acoustic wave resonator device of claim 15 wherein the first interposer includes a first intermediate conductive layer, a second intermediate conductive layer, and a temperature compensation layer sandwiched between the first intermediate conductive layer and the second intermediate conductive layer.

19. The film bulk acoustic wave resonator device of claim 18 wherein a thickness of the first intermediate conductive layer and the second intermediate conductive layer of the first interposer is larger than a thickness of the first conductive layer and the second conductive layer.

20. A packaged module comprising:
a packaging substrate;
an acoustic wave filter on the packaging substrate and configured to filter a radio frequency signal, the acoustic wave filter including a bulk acoustic wave (BAW) device, the BAW device including a first electrode, a second electrode, a stack of at least two first piezoelectric material layers of a same polarity type sandwiched between the first electrode and the second electrode, and a first interposer sandwiched between the at least two first piezoelectric material layers and including at least one intermediate electrode, the BAW device being configured to excite an even overtone mode as a main mode of operation; and
a radio frequency component electrically coupled to the acoustic wave filter and positioned on the packaging substrate, the acoustic wave filter and the radio frequency component being enclosed within a common package.
